(19) United States
(12) Patent Application Publication
(10) Pub. No.: US 2014/0241055 A1
(43) Pub. Date: Aug. 28, 2014

(54) Method and System for Reducing the Complexity of Electronically Programmable Nonvolatile Memory

(71) Applicant: INFINEON TECHNOLOGIES AG, Neubiberg (DE)

(72) Inventors: Ulrich Backhausen, Taufkirchen (DE); Thomas Kern, Muenchen (DE); Thomas Nirschl, Putzbrunn (DE); Jens Rosenbusch, Muenchen (DE)

(73) Assignee: Infineon Technologies AG, Neubiberg (DE)

(21) Appl. No.: 13/775,310

(22) Filed: Feb. 25, 2013

(51) Int. Cl. G11C 16/10; G11C 7/06; G11C 5/06

(52) U.S. Cl. CPC G11C 16/10; G11C 5/06; G11C 7/06
USPC 365/185.03; 365/72; 365/207

(57) ABSTRACT

Embodiments relate to memory devices and methods for firmly programming at least a portion of a plurality of electronically programmable and erasable nonvolatile memory cells in a processing of the nonvolatile memory devices.

### FIELD

The present disclosure relates generally to methods and systems for reducing the complexity of electronically programmable nonvolatile memory, and—in particular—the complexity of embedded flash memory such as hot source triple poly (HS3P) flash memory.

### BACKGROUND

Electronically programmable and erasable nonvolatile memories typically need some overhead circuitry to be operated. For instance, charge pumps need to be implemented to provide increased voltages for the operation of the nonvolatile memory cells. Furthermore, at the startup of a nonvolatile memory device, the charge pumps may need some time to power up before being fully functional.

Moreover, to securely read memory cells of the nonvolatile memory device, complex sense amplifiers might be needed to avoid misinterpretation of memory cell contents due to relatively low distances between logical signal levels. Furthermore, due to the operation principles of an electronically programmable nonvolatile memory as a cycled memory, the duration of a read cycle may set undesired lower limits to content access times for certain applications.

Hence, the characteristics of typical electronically programmable nonvolatile memories may lead to a relatively high complexity and performance limits for certain applications. A typical example for such an application may be the fast and reliable access to nonvolatile memory content in the boot or startup procedure of an automotive electronic control unit (ECU) into which the nonvolatile memory has been embedded.

For these or other reasons, there is a need for the present disclosure.

### SUMMARY

A method and system for reducing the complexity of nonvolatile memory is provided, substantially as shown in and/or described in connection with at least one of the figures, as set forth more completely in the claims.

Further features and advantages of embodiments will become apparent from the following detailed description made with reference to the accompanying drawings.

### BRIEF DESCRIPTION OF THE DRAWINGS

The accompanying drawings are included to provide a further understanding and are incorporated in and constitute a part of this specification. The drawings relate to examples and embodiments and together with the description serve to explain the principles of the disclosure. Other embodiments and many of the intended advantages of embodiments will be readily appreciated as they become better understood by reference to the following detailed description.

FIG. 1 shows a possible simplified layout for an electronically programmable and erasable nonvolatile memory that may be firmly programmed during a manufacturing step of a corresponding memory device by a processing mask that will establish or omit contacts between predetermined memory cells as well as bitlines and/or source lines according to an embodiment;

FIG. 2 shows a simplified schematic corresponding to the layout in FIG. 1 according to a first embodiment wherein source lines—for connecting the sources of the select transistors of corresponding rows of nonvolatile memory cells—run parallel to corresponding wordlines connecting the select gates of the select transistors of the corresponding rows of nonvolatile memory cells;

FIG. 3 shows a simplified schematic according to a second embodiment wherein source lines—for connecting the sources of the select transistors of corresponding columns of nonvolatile memory cells—run parallel to corresponding bitlines for connecting the drains of the floating gate transistors of the corresponding columns of nonvolatile memory cells; and

FIG. 4 shows a flow diagram of an embodiment for a method for programming at least a portion of a plurality of electronically programmable and erasable nonvolatile memory cells in a processing step of the nonvolatile memory device.

### DETAILED DESCRIPTION

In the following Detailed Description, reference is made to the accompanying drawings, which form a part hereof, and in which are shown by way of illustration specific embodiments. It is to be understood that other embodiments may be utilized and structural or other changes may be made without departing from the scope of the present disclosure. The following detailed description, therefore, is not to be taken in a limiting sense, and the scope of the present disclosure is defined by the appended claims.

In the following, for illustration purposes, the disclosure will be described with reference to flash memory as embedded nonvolatile memory (eNVM) for automotive applications. However, the disclosure is not so limited and may find its application in conjunction with reducing the complexity of any other kind of electronically programmable nonvolatile memory.

Embodiments of the disclosure may reduce the complexity of small integrated circuit products where it is favorable to combine different circuit functions into one module or nonvolatile memory device. In particular, the nonvolatile function of an electronically programmable nonvolatile memory device—that may, for instance, comprise floating gate transistors in nonvolatile memory cells—may be combined with a data persistent Read Only Memory (ROM) functionality. This combination may be implemented by firmly programming at least a portion of the electronically programmable and erasable nonvolatile memory cells through the usage of a processing mask that establishes or omits fixed connections such as by via contacts to predetermined select or floating gate transistors of the electronically programmable and erasable nonvolatile memory cells.

In this regard, in some embodiments, the firm programming may be implemented by a processing mask for via contacts for an integrated nonvolatile memory device. However, the fixed connections for firm programming of electronically programmable and erasable nonvolatile memory cells may also be established or omitted to the electronically programmable and erasable nonvolatile memory cells by any other suitable processing mask such as a processing mask for a specific metal or polysilicon layer.

In embodiments, the mask programmable portion of the electronically programmable and erasable nonvolatile memory device may be read with the same sense amplifiers that are used for the electronically programmable portion of the electronically programmable and erasable nonvolatile memory device. In this regard, the sense amplifiers and other overhead circuitry may be re-used instead of providing dedicated infrastructure circuitry for a conventional ROM portion within the electronically programmable and erasable nonvolatile memory device.

Moreover, in embodiments, the firmly programmed electronically programmable and erasable nonvolatile memory cells may reduce the requirement for charge pumps. In conventional electronically programmed nonvolatile memory cells, such charge pumps may also be necessary to provide elevated read voltages at the control gates of the floating gate transistors of nonvolatile memory cells during read access operations.

However, since in firmly programmed electronically programmable and erasable nonvolatile memory cells the no-current “programmed” mode is typically very distinct due to an omitted connection of the select transistor to the source line or of the floating gate transistor to the bitline, pumped reading voltages are typically not needed to distinguish if a firmly programmed electronically programmable and erasable nonvolatile memory cell represents a logical one state or a logical zero state.

As a result of these firmly established or omitted connections firmly programmed by a processing mask, the data retention of the firmly programmed electronically programmable and erasable nonvolatile memory cells—representing the ROM part of the electronically programmable and erasable nonvolatile memory device—may practically be infinite. As a further result, the information content of such ROM part may be more reliable than the information content of the electronically programmed portion of the nonvolatile memory device. This results from the fact that latter information content may be cycled or altered by write operations. Moreover, the electronically programmed information content may even need periodic refreshments in order to avoid its possible misinterpretation due to gradual loss of charge on the floating gates of floating gate transistors or wear of the gate oxide of the floating gate transistors in an electronically programmed nonvolatile memory cell due to an excessive number of write operations.

As a result of the above explained increased reliability of the information content in the firmly programmed electronically programmable and erasable nonvolatile memory cells, no disturbing effects or disturbs such as information content cycling, supply voltage fluctuations or spikes as well as alpha particle strikes may decisively affect the correct interpretation of the information content of the ROM part of the electronically programmable and erasable nonvolatile memory device.

In certain embodiments, the read access time to a certain bit of information stored in the firmly programmed portion of electronically programmable and erasable nonvolatile memory device may be reduced or minimized by selecting a plurality—in particular two adjacent—firmly programmed nonvolatile memory cells to represent the certain bit of information. In this way, the current delivered by the firmly programmed nonvolatile memory cells is correspondingly increased and serves to change the voltage level of the associated bitline representing the memory cells' logic content in a correspondingly shorter period of time. As a result, the logic content, in other words, the certain bit of information may be accessed faster in the firmly programmed portion of the electronically programmable and erasable nonvolatile memory device.

Hence, in embodiments, the information content of two memory cells associated with two wordlines may be combined to represent one bit of information to ensure good performance margin for reading the corresponding information content during power-up of a system using the firmly programmed electronically programmable and erasable nonvolatile memory. In other words, the increased number of memory cells per bit of information may be used to provide increased read access performance—for instance for boot applications—during power-up of a system with reduced access times to the information content.

In embodiments, during firmware development, the ROM portion of the electronically programmable and erasable nonvolatile memory may be alterable and implemented by a processing mask that may be applied in the manufacturing process of the corresponding memory device after verification of the developed firmware. In particular embodiments, hot source triple poly (HS3P) flash memory may comprise such firmly programmed electronically programmable and erasable nonvolatile memory as a ROM portion wherein the firm programming may be implemented by a contact processing mask.

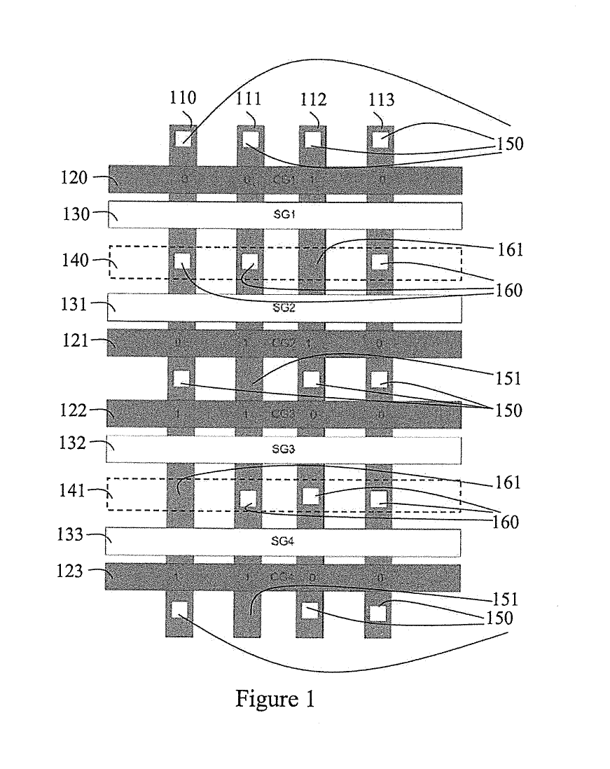

FIG. 1 shows a possible simplified layout for an electronically programmable and erasable nonvolatile memory that may be firmly programmed during a manufacturing step by a processing mask that will establish or omit electrical connections (e.g. contacts or vias) to bitlines or source lines according to an embodiment. In particular, FIG. 1 represents a possible layout of a plurality of two transistor (2T) electronically programmable and erasable nonvolatile memory cells that may be arranged in an array of four rows and four columns. As in the embodiment in FIG. 1, the four control gate lines (CG) 120, 121, 122 and 123 each may connect the control gates of four floating gate transistors of a row of four electronically programmable and erasable nonvolatile memory cells. As it is shown, the drains of the four floating gate transistors in the first row of memory cells—connected by first control gate line 120—may be connected to the four bitlines 110, 111, 112 and 113 respectively by a first row of four bitline contacts 150.

Moreover, the four select gate lines (SG) 130, 131, 132 and 133 each may connect the select gates of four select gate transistors of a row of four electronically programmable and erasable nonvolatile memory cells. As in this first embodiment, the current that may be drawn by the two uppermost rows of four electronically programmable and erasable nonvolatile memory cells may be collected from the sources of the corresponding two rows of four select gate transistors to the first source line 140 via the three source line contacts 160 in a first row of source line contacts. With respect to the two uppermost electronically programmable and erasable nonvolatile memory cells in the third column of electronically programmable and erasable nonvolatile memory cells connected by bitline 112, however, reference number 161 designates that a contact between the first source line 140 and the sources of the two select gate transistors of the two uppermost electronically programmable and erasable nonvolatile memory cells in the third column of memory cells may be omitted.

As a result, the two uppermost electronically programmable and erasable nonvolatile memory cells in the third column of electronically programmable and erasable nonvolatile memory cells cannot draw current from third bitline 112 such that the sense amplifier assigns the non-conducting cell state to a logical “1”. This is symbolized in FIG. 1 by the “1”s at the crossings of corresponding first and second control gate lines 120 and 121 with third bitline 112.

In contrast to that, e.g., the remaining three electronically programmable and erasable nonvolatile memory cells in the uppermost row of memory cells may draw current from first, second and forth bitlines 110, 111 and 113 respectively, in case the uppermost row of memory cells is selected by providing a high voltage at first select gate line 130 such that the sense amplifier assigns the conducting cell state to logical zeros as content of the corresponding memory cells. This is symbolized in FIG. 1 by the “0”s at the crossings of corresponding first control gate line 120 with first, second and forth bitlines 110, 111 and 113 respectively.

To summarize the above, a first way to firmly program a plurality of electronically programmable and erasable nonvolatile memory cells according to the embodiment in FIG. 1 may be to establish source line contacts 160 or omit source line contacts 161 to a predetermined source line by a suitable e.g. lithographical processing mask.

Now, a further way to firmly program a plurality of electronically programmable and erasable nonvolatile memory cells is shown in the second row of memory cells in FIG. 1. In this context, it is pointed out that in the embodiment of FIG. 1, the layout of the second uppermost row of electronically programmable and erasable nonvolatile memory cells may be regarded as a mirrored version of the layout of the uppermost row of electronically programmable and erasable nonvolatile memory cells being mirrored at the first source line 140. As a result, just as in FIG. 1, the corresponding second select gate line 131 of the second uppermost row of memory cells may be arranged next to first source line 140 while second control gate line 121 of the second uppermost row of memory cells may be arranged between second select gate line 131 and a second row of bitline contacts 150 connecting the drains of floating gate transistors of the second uppermost row of memory cells with the first, third and forth bitlines 110, 112 and 113.

Now in contrast to the first row of bitline contacts 150 at the upper edge of FIG. 1 comprising a bitline contact 150 to each of the bitlines 110, 111, 112 and 113, a bitline contact may be omitted as it is the case in the second row of bitline contacts where reference number 151 designates that the drain of the second floating gate transistor in the second row of memory cells is not connected to second bitline 111.

To summarize the above, a second way to firmly program a plurality of electronically programmable and erasable nonvolatile memory cells according to the embodiment in FIG. 1 may be to establish bitline contacts 150 or omit bitline contacts 151 to a predetermined bitline by a suitable e.g. lithographical processing mask.

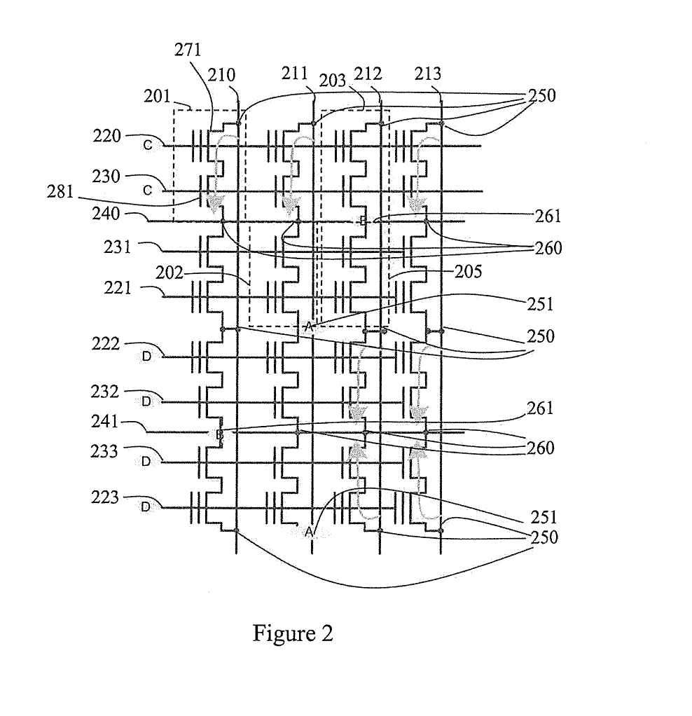

Turning now to the next Figure, this FIG. 2 shows a schematic corresponding to the layout in FIG. 1 wherein corresponding items have been designated with reference numbers that exhibit the same two rightmost digits. In this first embodiment, two horizontal source lines 240 and 241—for connecting the sources of the select transistors of corresponding rows of nonvolatile memory cells—run parallel to four corresponding select gate lines or wordlines 230, 231, 232 and 233 connecting the select gates of the select transistors of the corresponding four rows of nonvolatile memory cells. As shown in FIG. 2, the first electronically programmable and erasable nonvolatile memory cell 201 in the first row and the first column of the array of memory cells in FIG. 2 may comprise a first floating gate transistor 271 and a first select transistor 281.

Also from FIG. 2, it can be seen that the third memory cell 203 in the first row of memory cells may be programmed to a logical one by omitting the source line sided contact as designated with the letter “B” or the reference number 261. I.e. the third memory cell 203 cannot draw current even if it is selected by first select gate line or wordline 230 since there may be—as it is the case in the example in FIG. 2—no contact from the source of the select transistor of the third memory cell 203 to the first source line 240. The other three memory cells of the first row of memory cells, however, may all be connected to the first source line 240 by the first row of source line contacts 260, and—thus—all be programmed to logical zeros since, on the other hand, the four drains of the four floating gate transistors of the first row of memory cells may all be connected to the four bitlines 210, 211, 212 and 213 respectively by the first row of bitline contacts 250 as in FIG. 2.

Moreover, FIG. 2 also shows that the second memory cell 202 in the second row of memory cells may be programmed to a logical one by omitting the bitline sided contact to the second bitline 211 as designated with the letter “A” and the reference number 251. I.e. the second memory cell 202 cannot draw current even if it is selected by second select gate line or wordline 231 since there may be—as it is the case in the example in FIG. 2—no contact from the drain of the floating gate transistor of the second memory cell 202 to the second bitline 211. The other memory cells of the second row of memory cells, however, may all be connected to the first, third and forth bitline 210, 212 and 213 respectively by the second row of bitline contacts 250.

Furthermore, FIG. 2 shows that the third memory cell 205 in the second row of memory cells may be programmed by the same omitted source contact “B” to the first source line 240 at reference number 261 as the third memory cell 203 in the first row of memory cells.

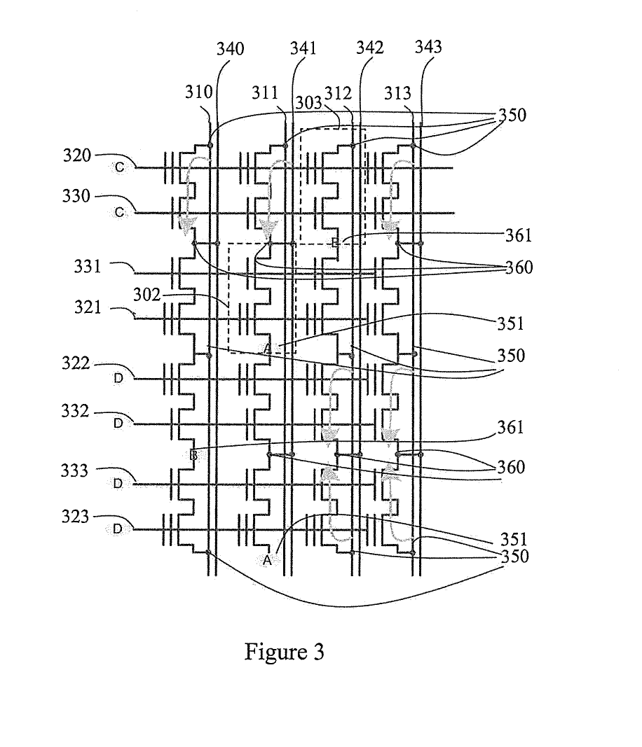

Turning now to the next Figure, this FIG. 3 shows a schematic according to a second embodiment wherein items corresponding to the items of FIG. 1 or 2 have been designated with reference numbers that exhibit the same two rightmost digits. In this second embodiment, four vertical source lines 340, 341, 342 and 343—for connecting the sources of the select transistors of corresponding four columns of nonvolatile memory cells—run parallel to four corresponding bitlines 310, 311, 312 and 313 respectively for connecting the drains of the floating gate transistors of the corresponding four columns of nonvolatile memory cells.

Also from FIG. 3, it can be seen that the third memory cell 303 in the first row of memory cells may be programmed to a logical one by omitting the source line sided contact as designated with the letter “B” or the reference number 361. I.e. the third memory cell 303 cannot draw current even if it is selected by first select gate line or wordline 330 since there may be—as it is the case in the example in FIG. 3—no contact from the source of the select transistor of the third memory cell 303 to the third source line 342. The other two memory cells of the third column of memory cells, however, may be connected to the third source line 342 by a lower common source line contact 360 between the third and the forth row of memory cells, and—thus—be both programmed to logical zeros since, on the other hand, the four drains of the four floating gate transistors of the third column of memory cells may all be connected to the third bitline 312 by a third column of bitline contacts 350 as in FIG. 3.

Moreover, FIG. 3 also shows that the second memory cell 302 in the second row of memory cells may be programmed to a logical one by omitting the bitline sided contact to the second bitline 311 as designated with the letter “A” or the reference number 351. I.e. the second memory cell 302 cannot draw current even if it is selected by second select gate line or wordline 331 since there may be—as it is the case in the example in FIG. 3—no contact from the drain of the floating gate transistor of the second memory cell 302 to the second bitline 311. The other memory cells of the second row of memory cells, however, may all be connected to the first, third and forth bitlines 310, 312 and 313 respectively, by a second row of bitline contacts 350.

From both FIG. 2 and FIG. 3 it can be seen that the layout of the second row of memory cells—which appears as the first row of memory cells being mirrored at the first source line 140 in FIG. 1 finds its parallel expression in the correspondingly mirrored schematics in FIG. 2 and FIG. 3. This mirrored configuration may be used to represent one word of information content either by a single row of memory cells or by two adjacent rows of memory cells that are mirrored with respect to the same source line.

In other words, letter “C” at the first control gate line 220 or 320 and the first select gate line 230 or 330 expresses that a read operation may be performed by the selection of a single wordline such as wordline 230 or 330. In this way, a low power read operation may be implemented since only one memory cell is used to represent one bit of information. This leads to only one memory cell possibly drawing current per bit of information depending on the definition whether a current drawing memory cell represents a logical zero, as in this example, or a logical one as in possible other examples. Consequently, the four memory cells in the first row of memory cells represent four bits of information.

In contrast to the above, letter “D” at the third and forth control gate lines 222 and 223 (or 322 and 323) as well as at the third and forth select gate lines 232 and 233 (or 332 and 333) expresses that a read operation may be performed by the selection of two adjacent wordlines such as wordlines 232 and 233 (or 332 and 333). In this way, a high speed read operation may be implemented since two memory cells are used to represent one bit of information. This leads to two memory cells with double the cell current in the conducting state. Consequently, the sense amplifier may detect the corresponding logical level faster than in the case of the current driven merely by one memory cell.

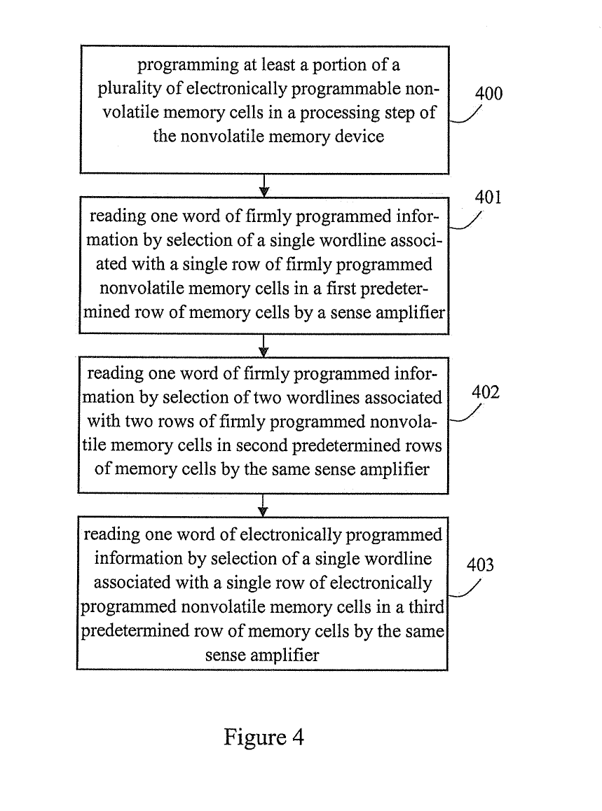

FIG. 4 shows a flow diagram of an embodiment for a method for programming at least a portion of a plurality of electronically programmable and erasable nonvolatile memory cells in a processing step of the nonvolatile memory device. At 400 of the method, at least a portion of the plurality of electronically programmable and erasable nonvolatile memory cells may be programmed in a processing act of the nonvolatile memory device.

At 401 of the method, one word of firmly programmed information may be read by selection of a single wordline associated with a single row of firmly programmed electronically programmable and erasable nonvolatile memory cells in a first predetermined row of memory cells by a sense amplifier.

At 402 of the method, one word of firmly programmed information may be read by selection of two wordlines associated with two rows of firmly programmed electronically programmable and erasable nonvolatile memory cells in second predetermined rows of memory cells by the same sense amplifier.

According to 403 of the method, one word of electronically programmed information is read by selection of a single wordline associated with a single row of electronically programmed nonvolatile memory cells in a third predetermined row of memory cells by the same sense amplifier.

With respect to the above-described embodiments which relate to the Figures, it is emphasized that the embodiments basically served to increase the comprehensibility. In addition to that, the following further embodiments try to illustrate a more general concept. However, also the following embodiments are not to be taken in a limiting sense. Rather—as expressed before—the scope of the present disclosure is defined by the appended claims.

In this regard, one embodiment relates to a nonvolatile memory device comprising a plurality of electronically programmable and erasable nonvolatile memory cells, at least a portion of which configured to be programmed by a processing mask configured to establish or omit connections to predetermined ones of the plurality of nonvolatile memory cells.

In an embodiment of the memory device, the processing mask is configured to be used after a verification in a manufacturing process of the nonvolatile memory device. This may allow an adoption of the firmly programmed portion to the results of the verification by altering the processing mask.

According to an embodiment, the processing mask is a mask configured to establish or omit contacts or vias to predetermined transistors of predetermined ones of the plurality of nonvolatile memory cells.

In embodiments, the processing mask is configured to program predetermined ones of the plurality of nonvolatile memory cells by establishing or omitting contacts or vias of the predetermined ones of the plurality of nonvolatile memory cells to associated bitlines.

In a further embodiment, the processing mask is configured to program predetermined ones of the plurality of nonvolatile memory cells by establishing or omitting contacts or vias of the predetermined ones of the plurality of nonvolatile memory cells to associated source lines.

A further embodiment relates to a nonvolatile memory device comprising electronically programmable and erasable nonvolatile memory cells, at least a portion of which is configured to be firmly programmed in a processing of the nonvolatile memory device.

An embodiment of the nonvolatile memory device further comprises sense amplifiers for reading the nonvolatile memory cells, wherein the sense amplifiers are configured to be re-used for reading the firmly programmed portion of the nonvolatile memory cells.

A further embodiment of the nonvolatile memory device is configured to read the firmly programmed portion of the nonvolatile memory cells without using charge pumps.

A still further embodiment of the nonvolatile memory device is configured to read one bit of firmly programmed information by selection of a single wordline associated with a single firmly programmed nonvolatile memory cell.

According to an embodiment, the memory device is configured to read one bit of firmly programmed information by selection of at least two wordlines associated to at least two firmly programmed nonvolatile memory cells.

A further embodiment relates to a nonvolatile memory device comprising at least one electronically programmable and erasable nonvolatile memory cell being firmly programmed as Read Only Memory (ROM) during manufacturing of the nonvolatile memory device.

In an embodiment, the at least one nonvolatile memory cell is a hot source triple poly (HS3P) flash cell.

According to an embodiment, the at least one nonvolatile memory cell is configured to be firmly programmed by a processing mask to establish or omit connections to the firmly programmed nonvolatile memory cell, wherein the processing mask is alterable during development of firmware stored on the memory device.

In an embodiment, an access time to one bit of information of the firmly programmed ROM is reduced by selecting a plurality of adjacent firmly programmed electronically programmable and erasable nonvolatile memory cells to represent the one bit.

In a further embodiment, at least one sense amplifier is shared between electronically programmable and erasable nonvolatile memory cells—that are writeable and exhibit nonvolatile functionality of electronically programmable and erasable nonvolatile memory—and firmly programmed electronically programmable and erasable nonvolatile memory cells—that are not writable and exhibit data persistent ROM functionality.

A further embodiment relates to a method for programming a nonvolatile memory comprising programming at least a portion of a plurality of electronically programmable and erasable nonvolatile memory cells by a processing mask configured to establish or omit connections to predetermined ones of the plurality of nonvolatile memory cells.

In an embodiment, the programming comprises using the processing mask after a verification in a manufacturing process of the nonvolatile memory device.

In another embodiment, the processing mask is a mask establishing or omitting contacts or vias to predetermined transistors of predetermined ones of the plurality of nonvolatile memory cells.

In a still further embodiment, the processing mask programs predetermined ones of the plurality of nonvolatile memory cells by establishing or omitting contacts or vias of the predetermined ones of the plurality of nonvolatile memory cells to associated bitlines.

According to an embodiment, the processing mask programs predetermined ones of the plurality of nonvolatile memory cells by establishing or omitting contacts or vias of the predetermined ones of the plurality of nonvolatile memory cells to associated source lines.

A further embodiment relates to a method for programming a nonvolatile memory comprising firmly programming at least a portion of a plurality of electronically programmable and erasable nonvolatile memory cells in a processing of the nonvolatile memory device.

A further embodiment of the method comprises sense amplifiers for reading the nonvolatile memory cells. This embodiment of the method further comprises re-using the sense amplifiers for reading the firmly programmed portion of the nonvolatile memory cells.

Another embodiment of the method further comprises reading the firmly programmed portion of the nonvolatile memory cells without using charge pumps.

An embodiment of the method further comprises reading one bit of firmly programmed information by selection of a single wordline associated with a single firmly programmed nonvolatile memory cell.

According to an embodiment, the method further comprises reading one bit of firmly programmed information by selection of at least two wordlines associated with at least two firmly programmed nonvolatile memory cells.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. A nonvolatile memory device, comprising:
a plurality of electronically programmable and erasable nonvolatile memory cells, at least a portion of which configured to be programmed by a processing mask configured to establish or omit connections to predetermined ones of the plurality of nonvolatile memory cells.

2. The memory device of claim 1, wherein the processing mask is configured to be used after a verification step in a manufacturing process of the nonvolatile memory device.

3. The memory device of claim 1, wherein the processing mask is a mask configured to establish or omit contacts or vias to predetermined transistors of predetermined ones of the plurality of nonvolatile memory cells.

4. The memory device of claim 1, wherein the processing mask is configured to program predetermined ones of the plurality of nonvolatile memory cells by establishing or omitting contacts or vias of the predetermined ones of the plurality of nonvolatile memory cells to associated bitlines.

5. The memory device of claim 1, wherein the processing mask is configured to program predetermined ones of the plurality of nonvolatile memory cells by establishing or omitting contacts or vias of the predetermined ones of the plurality of nonvolatile memory cells to associated source lines.

6. A nonvolatile memory device, comprising:
electronically programmable and erasable nonvolatile memory cells, at least a portion of which configured to be firmly programmed in a processing of the nonvolatile memory device.

7. The memory device of claim 6, further comprising sense amplifiers for reading the nonvolatile memory cells, wherein the sense amplifiers are configured to be re-used for reading the firmly programmed portion of the nonvolatile memory cells.

8. The memory device of claim 6, configured to read the firmly programmed portion of the nonvolatile memory cells without using charge pumps.

9. The memory device of claim 6, configured to read one bit of firmly programmed information by selection of a single wordline associated with a single firmly programmed nonvolatile memory cell.

10. The memory device of claim 6, configured to read one bit of firmly programmed information by selection of at least two wordlines associated with at least two firmly programmed nonvolatile memory cells.

11. A nonvolatile memory device, comprising:
at least one electronically programmable and erasable nonvolatile memory cell firmly programmed as Read Only Memory (ROM) during manufacturing of the nonvolatile memory device.

12. The memory device of claim 11, wherein the at least one nonvolatile memory cell is a hot source triple poly (HS3P) flash cell.

13. The memory device of claim 11, wherein the at least one nonvolatile memory cell is configured to be firmly programmed by a processing mask to establish or omit connections to the firmly programmed nonvolatile memory cell, wherein the processing mask is alterable during development of firmware stored on the memory device.

14. The memory device of claim 11, wherein an access time to one bit of information of the firmly programmed ROM is reduced by selecting a plurality of adjacent firmly programmed electronically programmable and erasable nonvolatile memory cells to represent the one bit.

15. The memory device of claim 11, wherein at least one sense amplifier is shared between electronically programmable and erasable nonvolatile memory cells—that are writeable and exhibit nonvolatile functionality of electronically programmable and erasable nonvolatile memory—and firmly programmed electronically programmable and erasable nonvolatile memory cells—that are not writable and exhibit data persistent ROM functionality.

16. A method for programming a nonvolatile memory, comprising:
programming at least a portion of a plurality of electronically programmable and erasable nonvolatile memory cells by a processing mask configured to establish or omit connections to predetermined ones of the plurality of nonvolatile memory cells.

17. The method of claim 16, wherein the programming comprises:
using the processing mask after a verification in a manufacturing process of the nonvolatile memory device.

18. The method of claim 16, wherein the processing mask is a mask establishing or omitting contacts or vias to predetermined transistors of predetermined ones of the plurality of nonvolatile memory cells.

19. The method of claim 16, wherein the processing mask programs predetermined ones of the plurality of nonvolatile memory cells by establishing or omitting contacts or vias of the predetermined ones of the plurality of nonvolatile memory cells to associated bitlines.

20. The method of claim 16, wherein the processing mask programs predetermined ones of the plurality of nonvolatile memory cells by establishing or omitting contacts or vias of the predetermined ones of the plurality of nonvolatile memory cells to associated source lines.

21. A method for programming a nonvolatile memory, comprising:
firmly programming at least a portion of a plurality of electronically programmable and erasable nonvolatile memory cells in a processing of the nonvolatile memory device.

22. The method of claim 21, comprising sense amplifiers for reading the nonvolatile memory cells, the method further comprising:
re-using the sense amplifiers for reading the firmly programmed portion of the nonvolatile memory cells.

23. The method of claim 21, further comprising:
reading the firmly programmed portion of the nonvolatile memory cells without using charge pumps.

24. The method of claim 21, further comprising:
reading one bit of firmly programmed information by selection of a single wordline associated to a single firmly programmed nonvolatile memory cell.

25. The method of claim 21, further comprising:
reading one bit of firmly programmed information by selection of at least two wordlines associated to at least two firmly programmed nonvolatile memory cells.
